(19) United States
(12) Patent Application Publication
(10) Pub. No.: US 2009/0200068 A1
(43) Pub. Date: Aug. 13, 2009

(54) SUBSTRATE FOR MOUNTING SEMICONDUCTOR DEVICE

(75) Inventor: Makoto KAGAYA, Tokyo (JP)

Correspondence Address: YOUNG & THOMPSON, 209 Madison Street, Suite 500, ALEXANDRIA, VA, 22314, US

(73) Assignee: ELPIDA MEMORY, INC., Tokyo (JP)

(21) Appl. No.: 12/367,559

(22) Filed: Feb. 9, 2009

(30) Foreign Application Priority Data
Feb. 8, 2008 (JP) 2008-029485

(51) Int. Cl. H05K 1/11

(52) U.S. Cl. 174/255

(57) ABSTRACT

A substrate for mounting a semiconductor device comprises a first and a second group of input and output terminals and common terminals. The substrate further comprises conductive pads that use for inputting and outputting data from and to the semiconductor device, non-conductive pads that no use for inputting and outputting data from and to the semiconductor device, and common pads formed so as to correspond to the common terminals. The second group of input and output terminals are connected to the non-conductive pads and the common terminals are connected to the common pads when the first group of input and output terminals are connected to the conductive pads, while the first group of input and output terminals are connected to the non-conductive pads and the common terminals are connected to the common pads when the second group of input and output terminals are connected to the conductive pads.

This application is based upon and claims the benefit of priority from Japanese patent application No. JP 2008-029485, filed on Feb. 8, 2008, the disclosure of which is incorporated herein in its entirety by reference.

### FIELD OF THE INVENTION

The present invention relates to a substrate for mounting a semiconductor device and an electronic device using the substrate.

### BACKGROUND OF THE INVENTION

Recent reduction in size and improved performance of electronic equipment has led to increased degree of integration and size reduction of semiconductor elements used in the electronic equipment,

On the other hand, the increased degree of integration of semiconductor elements has made manufacturing processes more complex, resulting in increase of defectives.

As a result, remanufacturing techniques have assumed particularly high importance in this technical field.

An anti-fuse technique has been proposed and put in practical use as one of such remanufacturing techniques, which is capable of rescuing defective bits even after completion of assembly of a semiconductor memory (see, for example, Japanese Laid-Open Patent Publication No. 2004-335070 (Patent Document 1)). However, this technique, which aims at rescuing a few bits (a few addresses), cannot solve the problem of defectiveness in single or several terminals of multi-address terminals.

On the other hand, in a memory device such as a semiconductor memory, even if some of input and output terminals become defective in conduction after assembly, other terminals are often still usable. Therefore, if a memory suffers the problem of defectiveness in single or several terminals of multi-address terminals, the memory can sometimes be remanufactured as a memory with smaller memory capacity by utilizing only the usable terminals.

For example, Japanese Laid-Open Patent Publication No. H09-185898 (Patent Document 2) describes a technique in which semiconductor memories having a defective circuit are prepared in plurality and usable terminals thereof are connected to each other to remanufacture a semiconductor memory having a memory capacity equivalent to that of an original non-defective memory.

The present inventor has recognized the following points. Positions of defective terminals differ variously among defective devices. A substrate to mount a defective memory thereon is required to have connection portions (pads) configured corresponding to the positions of defective terminals. According to the technique described above, wiring lines must be laid out according to the positions of defective terminals, resulting in complex configuration on the substrate. In addition, the pattern for mounting the memory on the substrate becomes complex, which involves a lot of troubles.

### SUMMARY

The present invention seeks to solve one or more of the above problems, or to improve upon those problems at least in part.

In a first aspect, there is provided a substrate for mounting a semiconductor device which comprises a first group of input and output terminals, a second group of input and output terminals, and common terminals. The substrate comprises conductive pads that use for inputting and outputting data from and to the semiconductor device, non-conductive pads that no use for inputting and outputting data from and to the semiconductor device, and common pads formed so as to correspond to the common terminals. The second group of input and output terminals are connected to the non-conductive pads and the common terminals are connected to the common pads when the first group of input and output terminals are connected to the conductive pads. On the other hand, the first group of input and output terminals are connected to the non-conductive pads and the common terminals are connected to the common pads when the second group of input and output terminals are connected to the conductive pads.

In addition, the common pads may include a first pad and a second pad. In this case, the first pad is connected to the corresponding terminal in the common terminals when the first group of input and output terminals are connected to the conductive terminals and is no connected to the common terminals when the second group of input and output terminals are connected to the conductive pads. The second pad is no connected to the common terminals when the first group of input and output terminals are connected to the conductive pads and is connected to the corresponding terminal in the common terminals when the second group of input and output terminals are connected to the conductive terminals.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a plan view showing an example of an electronic device to which the present invention is applicable;

FIG. 2 is a plan view showing an example of the semiconductor device shown in FIG. 1;

FIG. 3 is a plan view showing an example of the module substrate shown in FIG. 1;

FIG. 4 is a diagram, as viewed from the top side, showing an example of arrangement of connection terminals in semiconductor device shown in FIG. 1;

FIG. 5 is a diagram showing an example of arrangement of connection pads in the mounting portion shown in FIG. 3;

FIG. 6 is a diagram showing arrangement of only the input and output terminals shown in FIG. 4;

FIG. 7 is a diagram showing arrangement of only the pads for the input and output terminals shown in FIG. 5;

FIG. 8 is a diagram showing a state in which the semiconductor device has been rotated by an angle of a from the state shown in FIG. 6 in a direction as indicated by the arrow A;

FIG. 9 is a diagram showing an example of arrangement of connection pads in a mounting portion of a module substrate;

FIG. 10 is a diagram, as viewed from the top side, showing an example of arrangement of connection terminals of a semiconductor device in an electronic device according to a second embodiment;

FIG. 11 is a diagram showing an example of arrangement of connection pads in a mounting portion in the electronic device according to the second embodiment:

FIG. 12 is a diagram for explaining a process for mounting the semiconductor device shown in FIG. 10 on the mounting portion shown in FIG. 11; and

FIG. 13 is a diagram for explaining another process for mounting the semiconductor device shown in FIG. 10 on the mounting portion shown in FIG. 11.

### DESCRIPTION OF EXEMPLARY EMBODIMENTS

Preferred exemplary embodiments of the present invention will be described in detail with reference to the drawings.

Those skilled in the art will recognize that many alternative embodiments can be accomplished using the teachings of the present invention and that the invention is not limited to the embodiments illustrated for explanatory purposes.

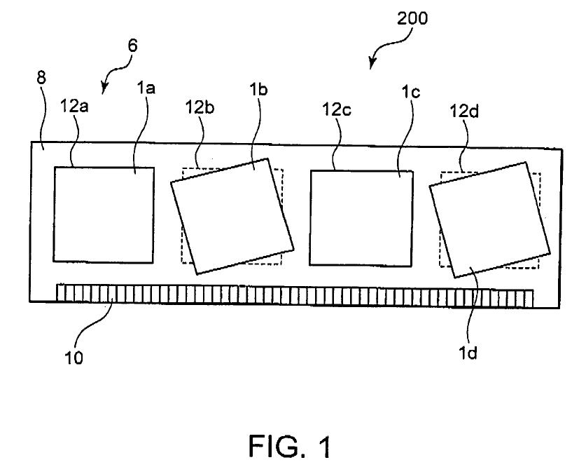

First, referring to FIGS. 1 to 3, the description will be made of schematic configurations of an electronic device 200 and components of the electronic device 200 according to a first embodiment of the present invention.

As shown in FIG. 1, the electronic device 200 includes memories or other semiconductor devices 1a, 1b, 1c, 1d and a module substrate 6 serving as a substrate (substrate for remanufacturing) for mounting the semiconductor devices 1a to 1d.

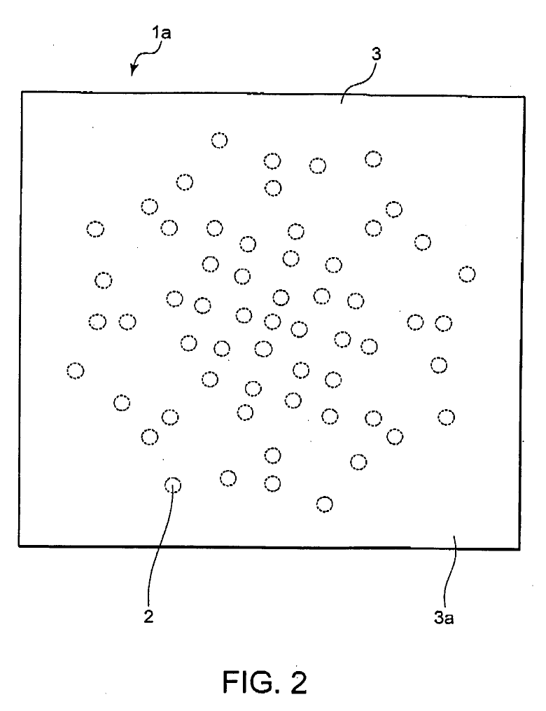

As shown in FIG. 2, the semiconductor device 1a includes a sub-substrate 3 having a rectangular plate shape in plan view. There is provided, in the inside of the sub-substrate 3, a semiconductor chip (not shown) having a memory circuit such as a DRAM (Dynamic Random Access Memory). There are provided, on the lower surface of the semiconductor device 1a, a plurality of connection terminals 2 serving as terminals for connecting the semiconductor device 1a to the module substrate 6. The shape of the connection terminals 2 is not limited particularly, and may be either a pin-like shape or a ball-like shape. The material of the connection terminals 2 is not particularly limited, either. The connection terminals 2 are electrically connected to the semiconductor chip (not shown) by means of a wire or internal wiring (not shown).

As described later, it is assumed in this embodiment that the semiconductor device 1a is a defective memory in which some of the connection terminals 2 are defective terminals which are not conductive. The semiconductor devices 1b, 1c, 1d have the same configuration as that of the semiconductor device 1a, and hence description thereof will be omitted.

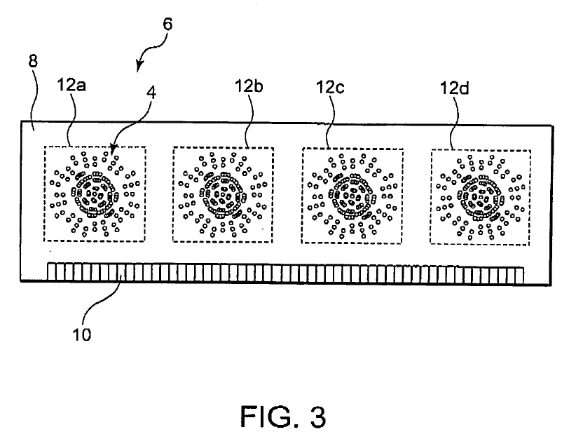

As shown in FIG. 3, the module substrate 6 includes a main substrate 8. The main substrate 8 has, on its surface, mounting portions 12a, 12b, 12c, 12d for mounting the semiconductor devices 1a, 1b, 1c, 1d thereon. The mounting portion 12a has connection pads 4 provided at positions corresponding to the connection terminals 2(FIG. 2), so that the connection terminals 2 of the semiconductor device 1a are connected to the connection pads 4. There are provided, at a side end of the main substrate 8, module substrate terminals 10 for electrically connecting the module substrate 6 to another substrate. The module substrate terminals 10 are connected to the connection pads 4 by means of wiring lines not shown.

The mounting portions 12b, 12c, 12d have the same configuration as that of the mounting portion 12a, and hence description thereof will be omitted here.

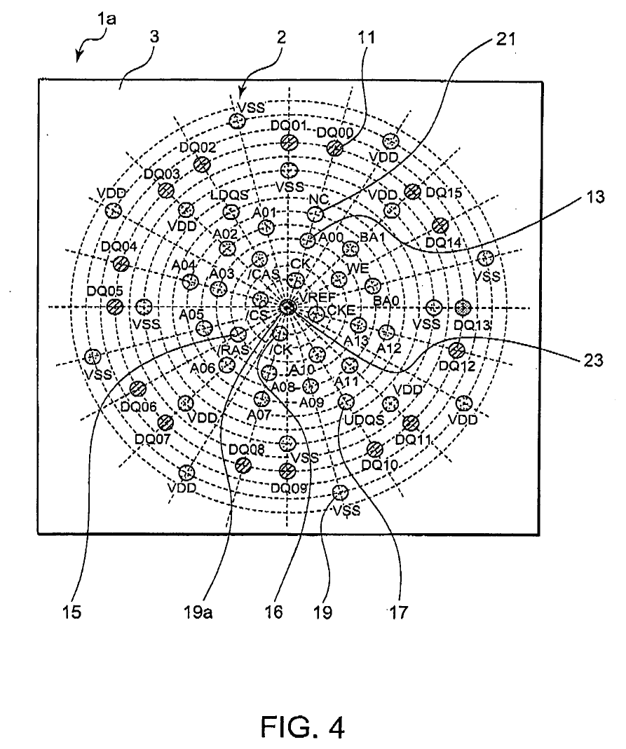

Referring to FIGS. 4 to 7, detailed description will be made of arrangement of the connection terminals 2 in the semiconductor device 1a, and arrangement of the connection pads 4 in the mounting portion 12a. Arrangement of the connection terminals 2 of the semiconductor devices 1b, 1c, and 1d is the same as that of the semiconductor device 1a, and arrangement of the connection pads 4 of the mounting portions 12b, 12c, 12d is the same as that of the mounting portion 12a. Therefore, description thereof will be omitted.

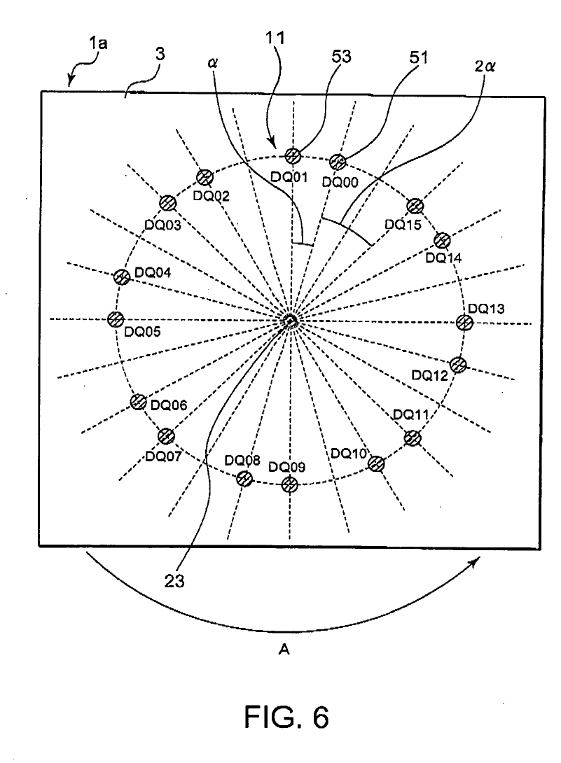

First, the arrangement of the connection terminals 2 of the semiconductor device 1a will be described with reference to FIGS. 4 and 6.

As shown in FIG. 4, the semiconductor device 1a has, on its lower surface, the connection terminals 2 consisting of 16 input and output terminals 11 indicated as DQ00 to DQ15, address terminals 13 indicated as A01 to A13, BA0 and BA1, command terminals 15 indicated as /RAS, /CAS, WE, CKE and /CS, clock terminals 16 indicated as CK and /CK, strobe terminals 17 indicated as UDQS and LDQS, power supply terminals 19 indicated as VSS and VDD, and a reference power supply terminal 19a indicated as VREF. The semiconductor device 1a further has non-conductive terminals 21 indicated as NC.

The input and output terminals 11, the address terminals 13, the command terminals 15, the clock terminals 16, the strobe terminals 17, and the power supply terminals 19 are respectively arranged concentrically such that the terminals of a same type are located at the same distance from a first center point 23 set on the surface (the surface facing the module substrate 6, that is, the lower surface) of the semiconductor device 1a. On the other hand, the reference power supply terminal 19a is provided such that the center thereof matches with the first center point 23.

As is obvious from FIGS. 4 and 6, the semiconductor device 1a is a so-called ×16 memory (16-terminal memory) having 16 input and output terminals 11 arranged along the circumference of a circle formed around the first center point 23. Taking the input and output terminal indicated as DQ00 as an example of the input and output terminals 11, the input and output terminal DQ00 is adjacent to the terminal DQ01 with a relatively small adjacent distance, and to the terminal DQ15 with a relatively large adjacent distance. On the other hand, the input and output terminal indicated as DQ01 is adjacent to the terminal DQ00 with a relatively small adjacent distance, and to the terminal DQ02 with a relatively large adjacent distance. When it is assumed that an angle of a is formed at the first center point 23 by the lines connecting between the first center point 23 and each pair of adjacent terminals having a relatively small adjacent distance (for example, DQ00 and DQ01), each pair of adjacent terminals having a relatively large adjacent distance (for example, DQ00 and DQ15) are provided to form an angle of 2a at the first center point 23 (see FIG. 6). Specifically, the input and output terminals 11 includes eight pairs of terminals with an angle of a (pairs of DQ00 and DQ01, DQ02 and DQ03, DQ04 and DQ05, DQ06 and DQ07, DQ08 and DQ09, DQ10 and DQ11, DQ12 and DQ13, and DQ14 and DQ15), while an angle of 2a is formed between the respective two pairs.

As shown in FIG. 4, the other terminals (common terminals), namely the address terminals 13, the command terminals 15, the clock terminals 16, and the strobe terminals 17 are arranged between the input and output terminals 11 and the first center point 23. This means that the distances from the first center point 23 to these terminals are shorter than the distance from first center point 23 to the input and output terminals 11.

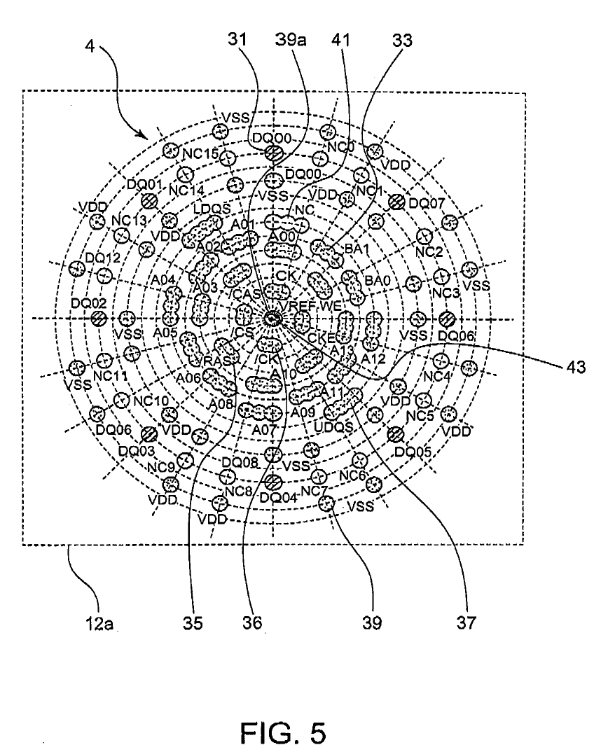

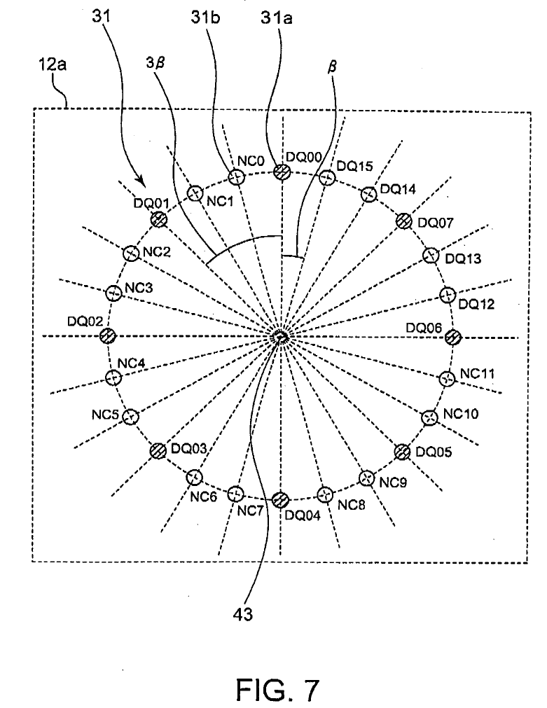

Next, the arrangement of the connection pads 4 of the mounting portion 12a will be described with reference to FIGS. 5 and 7.

As shown in FIG. 5, the mounting portion 12a has the connection pads 4 consisting of 24 input and output terminal pads 31 indicated as DQ00 to DQ07, and NC0 to NC15, address terminal pads 33 indicated as A01 to A13, BA0 and BA1, command terminal pads 35 indicated as /RAS, /CAS, WE, CKE and /CS, clock terminal pads 36 indicated as CK and /CK, strobe terminal pads 37 indicated as UDQS and LDQS, power supply terminal pads 39 indicated as VSS and VDD, and a reference power supply terminal pad 39a indicated as VREF. The mounting portion 12a further has other connection pads 4, or non-conductive terminal pads 41 indicated as NC.

The input and output terminal pads 31, the address terminal pads 33, the command terminal pads 35, the clock terminal pads 36, the strobe terminal pads 37, and the power supply terminal pads 39 are respectively arranged concentrically such that the terminals of a same type are at the same distance from a second center point (center point) 43 set on the surface (the face facing the semiconductor device 1a, that is, the upper surface) of the mounting portion 12a. This means that the address terminal pads 33, the command terminal pads 35, the clock terminal pads 36, the strobe terminal pads 37, and the power supply terminal pads 39 are formed at such positions that, when the semiconductor device 1a is mounted on the mounting portion 12a, the terminal pads come to positions corresponding to those of (positions where they can be connected to) the address terminals 13, the command terminals 15, the clock terminals 16, the strobe terminals 17, and the power supply terminals 19, respectively. On the other hand, the reference power supply terminal pad 39a is formed such that the center thereof matches with the second center point 43.

As shown in FIG. 7, the input and output terminal pads 31 are arranged at equal intervals along the circumference of a circle formed around the second center point 43, while the pads DQ00 to DQ07 are arranged at positions respectively corresponding to the terminals DQ01, DQ03, DQ05, DQ07, DQ09, DQ11 and DQ15 of the input and output terminals 11. Therefore, the radius of the circle along which the input and output terminal pads 31 are arranged is the same as the radius of the circle along which the input and output terminals 11 are arranged (see FIG. 6). Further, the input and output terminal pads 31 are arranged such that each of the pads DQ00 to DQ7 is interposed between two of the pads NC0 to NC15.

As is obvious from FIGS. 5 and 7, the eight pads DQ00 to DQ7 of the input and output terminal pads 31 are conductive pads 31a as a first group of pads for use in a so called ×8 memory (8-terminal memory). On the other hand, the 16 pads NC0 to NC15 are non-conductive pads 31b as a second group of pads.

As shown in FIG. 7, a pair of pads adjacent to each other with a minimum distance in the input and output terminal pads 31 forms an angle of β at the second center point 43, the angle of β being equal to the angle of α described above. A pair of conductive pads 31a adjacent to each other with a minimum distance forms an angle of 3β at the second center point 43.

On the other hand, as shown in FIG. 5, the other pads (common pads), namely, the address terminal pads 33, the command terminal pads 35, the clock terminal pads 36, and the strobe terminal pads 37 are arranged between the input and output terminal pads 31 and the second center point 43. This means that the distances from the second center point 43 to these terminal pads are smaller than the distance from the second center point 43 to the input and output terminal pads 31. The other pads include a pad which is larger in size than the conductive pads 31a and the non-conductive pads 31b.

The address terminal pads 33, the command terminal pads 35, the clock terminal pads 36, the strobe terminal pads 37, and the non-conductive terminal pads 41 are formed to have a circular arc shape in plan view. Each circular arc is defined by the angle of β.

Next, referring to FIG. 1 and FIGS. 6 to 8, description will be made of a method of remanufacturing the semiconductor devices 1a, 1b, 1c, 1d, when some of the input and output terminals 11 are defective terminals in at least one of the semiconductor devices 1a, 1b, 1c, 1d, by mounting the semiconductor devices 1a, 1b, 1c, 1d on the mounting portions 12a, 12b, 12c, 12d, respectively, to assemble the electronic device 200.

The description will be made on the assumption that the semiconductor devices 1a and 1c have input and output terminals 11 in which at least some of even-numbered terminals 51 (DQ00, DQ02, DQ04, DQ06, DQ08, DQ10, DQ12, DQ14) shown in FIG. 6 are defective terminal (first or second group of input and output terminals), while odd-numbered terminals 53 (DQ01, DQ03, DQ05, DQ07, DQ09, DQ11, DQ13, DQ15) are normal terminals (second or first group of input and output terminals).

In this case, the semiconductor devices 1a and 1c are mounted on the module substrate 6 such that the plane coordinates of the first center point 23 match with the plane coordinates of the second center point 43, and that the odd-numbered terminals 53, namely, the normal terminals face the conductive pads 31a.

More specifically, as shown in FIG. 1, the semiconductor devices 1a and 1c are mounted on the module substrate 6 such that they are not angularly deviated about the centers of the mounting portions. Thus, non-conductive pads 31b of the input and output terminal pads 31 are connected at the positions corresponding to the even-numbered terminals 51 in the mounting portion 12a (and the mounting portion 12c). As a result, the even-numbered terminals 51 including defective terminals are not used (see FIGS. 6 and 7). On the other hand, conductive pads 31a are connected at the positions corresponding to the odd-numbered terminals 53. Thus, the odd-numbered terminal 53 are usable in the electronic device 200.

In this manner, the semiconductor devices 1a and 1c can be remanufactured as ×8 memories using only eight odd-numbered terminals 53 (normal terminals).

Next, it is assumed that the semiconductor devices 1b and 1d of the semiconductor devices 1a, 1b, 1c, 1d have the input and output terminals 11 in which at least some of odd-numbered terminals 53 (DQ01, DQ03, DQ05, DQ07, DQ09, DQ11, DQ13, DQ15) shown in FIG. 6 are defective terminals and even-numbered terminals 51 (DQ00, DQ02, DQ04, DQ06, DQ08, DQ10, DQ12, DQ14) are normal terminals.

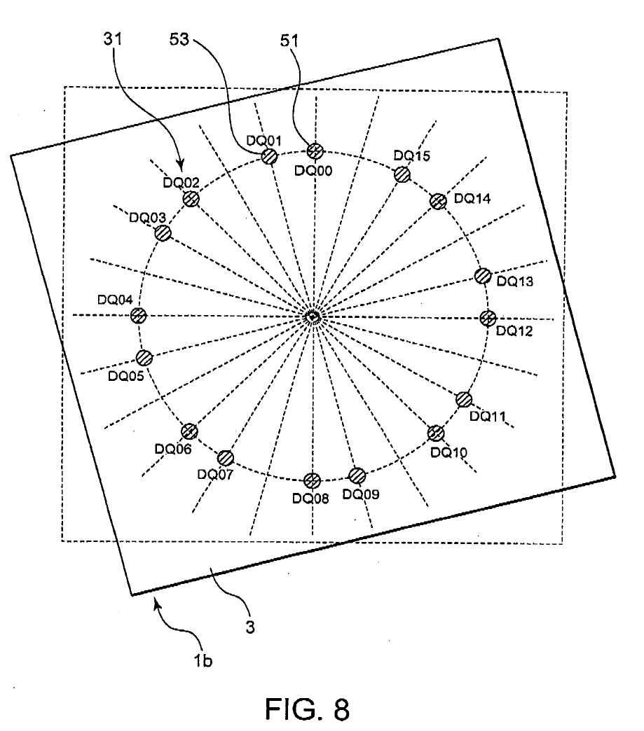

In this case, if the connection is performed in the same manner as when at least some of the even-numbered terminals 51 are defective terminals, the defective terminals (odd-numbered terminals 53) will be connected to the conductive pads 31a. To avoid this, before mounting, the semiconductor devices 1b and 1d are rotated by an angle of a in the direction indicated by the arrow A of FIG. 6 (anticlockwise) with the plane coordinates of the first center point 23 matching with the plane coordinates of the second center point 43 (see FIG. 8). As a result, as shown in FIG. 1, the semiconductor devices 1b and 1d are mounted on the module substrate 6 in the state in which they are rotated by an angle of a around the centers of the mounting portions 12b and 12d.

Thus, as shown in FIGS. 7 and 8, conductive pads 31a of the input and output terminal pads 31 are connected at the positions corresponding to the even-numbered terminals 51 in the mounting portion 12b (and the mounting portion 12d), while non-conductive pads 31b are connected at the positions corresponding to the odd-numbered terminal 53. As a result, the semiconductor devices 1b and 1d can be remanufactured as ×8 memories using only eight odd-numbered terminals 53 (normal terminals).

Regardless of whichever of the odd-numbered terminals 53 or the even-numbered terminals 51 are defective, only the normal terminals can be mounted on the conductive pads of the input and output terminal pads 31 in the mounting portions 12a, 12b, 12c and 12d, whereby the semiconductor devices can be manufactured as ×8 memories using only eight input and output terminals 11. This eliminates the need of laying around the wiring corresponding to the positions of the defective terminals, and makes the configuration of the module substrate 6 simpler than that of a conventional substrate for remanufacturing.

Further, the semiconductor devices can be mounted on the substrate either by mounting them without rotation or by mounting them after rotating them by a predetermined angle around the centers of the mounting portions. Since there are only these two methods available, it does not take much trouble to mount the semiconductor devices.

It should be understood that, even when the semiconductor device is mounted and connected after being rotated around the center of the mounting portion, the input and output terminal pads 31, the address terminal pads 33, the command terminal pads 35, the clock terminal pads 36, the strobe terminal pads 37, and the power supply terminal pads 39 can be connected to the corresponding terminals in the same manner as when the semiconductor device is not rotated, since the terminal pads have a circular arc shape defined by the angle of β and are provided at positions corresponding the respective terminals.

The electronic device 200 according to the first embodiment, as described above, includes a semiconductor device la having 16 input and output terminals 11 and a module substrate 6 having a mounting portion 12a with 24 input and output terminal pads 31, and is designed such that the semiconductor device can be mounted by rotating the same according to the position of a defective terminal, if any. This eliminates the need of laying around the wiring corresponding to the position of the defective terminal, and makes the configuration of the substrate simpler than that of a conventional substrate for remanufacturing. It does not take much trouble to mount the semiconductor device.

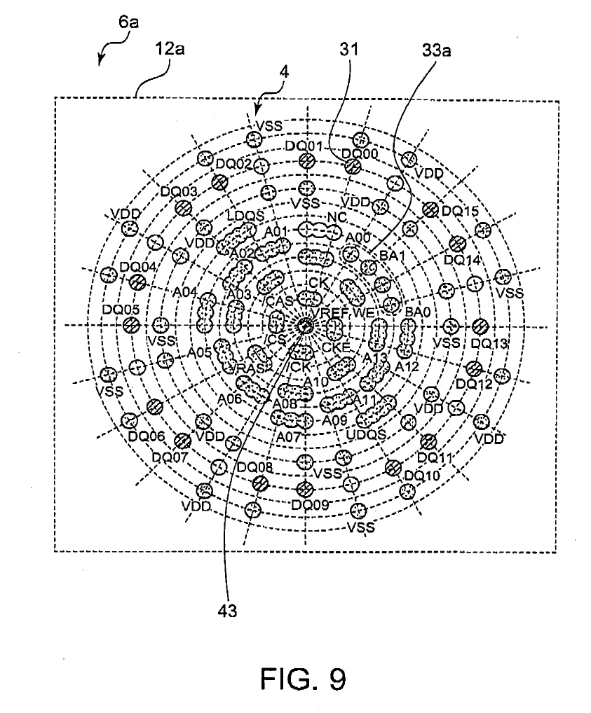

Next, description will be made of a module substrate 6a for use in an electronic device according to a second embodiment with reference to FIG. 9,

The module substrate 6a according to the second embodiment is different from the first embodiment in that each of address terminal pads 33a is formed by a plurality of separate pads (pad pieces), instead of being formed in a circular arc shape. In the description of the second embodiment below, elements having the same functions as those of the first embodiment are assigned with the same reference numerals and description thereof is omitted. For example, the semiconductor device 1a is the same as the one described In FIG. 4. The general configuration of the electronic device is the same as that of the electronic device 200 according to the first embodiment. Therefore, description thereof will be omitted here.

As shown in FIG. 9, in the module substrate 6a, each of address terminal pads 33a is formed by a plurality of separate pads instead of being formed in a circular arc shape. Each plurality of separate pads is arranged within a planar range defined by the (rotational) angle of a described above, and is electrically connected to each other in another layer.

In this manner, the pads other than the input and output terminal pads 31 and arranged between the input and output terminal pads 31 and the second center point 43 may be formed by a plurality of separate pads instead of being formed in a circular arc shape, and may be electrically connected to each other in another layer.

Like the electronic device 200 described in FIG. 1, an electronic device according to the second embodiment also includes a semiconductor device 1a having 16 input and output terminals 11, and a module substrate 6a having a mounting portion 12a having 24 input and output terminal pads 31, and is designed such that the semiconductor device can be mounted by rotating the same according to a position of a defective terminal, if any.

Accordingly, the second embodiment provides beneficial effects equivalent to those of the first embodiment.

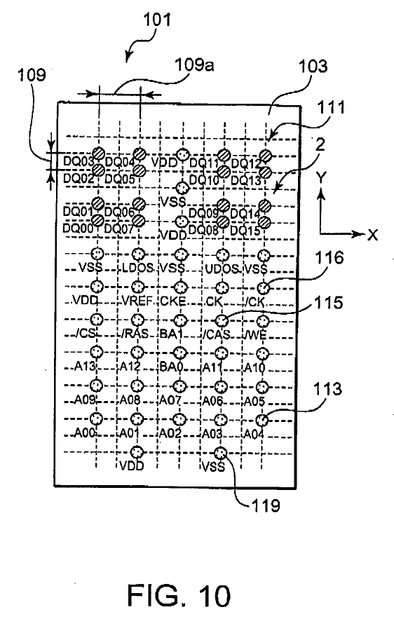

Next, description will be made of a semiconductor device 101 and a module substrate 106 for use in an electronic device according to a third embodiment, with reference to FIGS. 10 to 13.

Unlike the first embodiment, the semiconductor device 101 and the module substrate 106 according to the third embodiment respectively have a plurality of terminals and a plurality of pads arranged in a lattice pattern.

In the description of the third embodiment below, elements having the same functions as those of the first embodiment are assigned with the same reference numerals and description thereof is omitted. General configuration of the electronic device is also the same as that of the first embodiment, and hence description thereof will be omitted.

First, description will be made of a configuration of the semiconductor device 101, with reference to FIG. 10.

As shown in FIG. 10, the semiconductor device 101 includes a sub-substrate 103. Like the semiconductor device la described in FIG. 4, there are provided, on one surface of the sub-substrate 103 (the surface facing the module substrate 106, that is, the lower surface), connection terminals 2 consisting of 16 input and output terminals 111 indicated as DQ00 to DQ15, address terminals 113 indicated as A01 to A13, BA0 and BA1, command terminals 115 indicated as /RAS, /CAS, WE, CKE and /CS, clock terminals 116 indicated as CK and /CK, strobe terminals 117 indicated as UDQS and LDQS, power supply terminals 119 indicated as VSS and VDD, and a reference power supply terminal 119a indicated as VREF. These terminals are arranged in a lattice pattern with equal intervals.

For example, the terminals DQ00 and DQ01, and DQ02 and DQ03 of the input and output terminals 111 are arranged in a vertical direction (Y direction) at equal terminal intervals 109, while the terminals DQ04 and DQ05, and DQ06 and DQ07 are also arranged in a vertical direction at equal terminal intervals 109. Likewise, the terminals DQ08 and DQ09, and DQ10 and DQ11 are arranged in a vertical direction at equal terminal intervals 109, and the terminals DQ12 and DQ13, and DQ14 and DQ15 are also arranged in a vertical direction at equal terminal intervals 109.

On the other hand, the terminals DQ03 and DQ04, and DQ11 and DQ 12 are arranged in a crosswise direction (X direction) at equal terminal intervals 109a, and the terminals DQ02 and DQ05, and DQ10 and DQ13 are also arranged in a crosswise direction (X direction) at equal terminal intervals 109a. Likewise, the terminals DQ01 and DQ06, and DQ09 and DQ14 are arranged in a crosswise direction (X direction) at equal terminal intervals 109a, and the terminals DQ00 and DQ07, and DQ08 and DQ15 are also arranged in a crosswise direction (X direction) at equal terminal intervals 109a.

The power supply terminals 119 (VSS and VDD) are arranged in a Y direction between the columns formed by the terminals DQ04, DQ05, DQ06 and DQ07 and the terminals DQ08, DQ09, DQ10 and DQ11, at intervals twice as large as the terminal intervals 109a.

There are provided, below the input and output terminals 111 in FIG. 10, the address terminals 113, the command terminals 115, the clock terminals 116, the strobe terminals 117, the power supply terminals 119, and the reference power supply terminal 119a (VREF). These terminals are arranged in Y directions at intervals twice as large as the terminal intervals 109 of the input and output terminals 111.

As is obvious from FIG. 10, the semiconductor device 101 is a so-called ×16 memory having 16 input and output terminals 111.

In X directions, all the terminals are arranged at equal terminal intervals 109a.

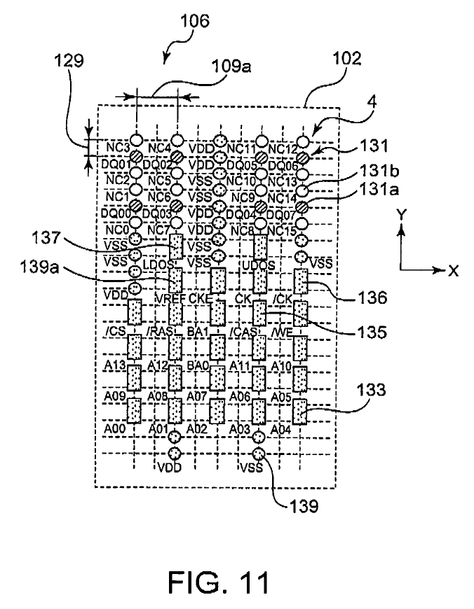

Next, a configuration of the mounting portion 102 will be described with reference to FIG. 11.

As shown in FIG. 11, like the mounting portion 12a described in FIG. 5, the mounting portion 102 has connection pads 4 consisting of input and output terminal pads 131 indicated as DQ00 to DQ07 and NC0 to NC15, address terminal pads 133 indicated as A01 to A13, BA0 and BA1, command terminal pads 135 indicated as /RAS, /CAS, WE, CKE and /CS, clock terminal pads 136 indicated as CK and /CK, strobe terminal pads 137 indicated as UDQS and LDQS, power supply terminal pads 139 indicated as VSS and VDD, and a reference power supply terminal pad 139a indicated as VREF, and these connection pads are arranged in a lattice pattern.

The input and output terminal pads 131 include conductive pads 131 a indicated as DQ00 to DQ07, and non-conductive pads 131b indicated as NC0 to NC15.

In the state as shown in FIG. 11, the pads DQ00 to DQ07 are provided at the positions corresponding to the input and output terminals 111 indicated as DQ00, DQ02, DQ05, DQ07, DQ08, DQ10, DQ13 and DQ15 in FIG. 10, and each of the pads DQ00 to DQ7 is arranged to be interposed between two pads of the pads NC0 to NC15. This means that eight of the input and output terminal pads 131, namely, the pads DQ00 to DQ7 are conductive pads 131a, being pads for a so-called ×8 memory.

All the input and output terminal pads 131 are arranged in Y directions at equal pad intervals 129, which are equal to the terminal intervals 109 of the semiconductor device 101 shown in FIG. 10.

On the other hand, the connection pads other than the input and output terminal pads 131, namely the address terminal pads 133, the command terminal pads 135, the clock terminal pads 136, and the strobe terminal pads 137 each have a rectangular shape elongated in a Y direction (upwards in FIG. 10) in comparison with the input and output terminal pads 131. These rectangular pads have a length approximately equal to the sum of the pad interval 129 plus the length of the input and output terminal pads 131, extending beyond two adjacent cross points of the lattice pattern.

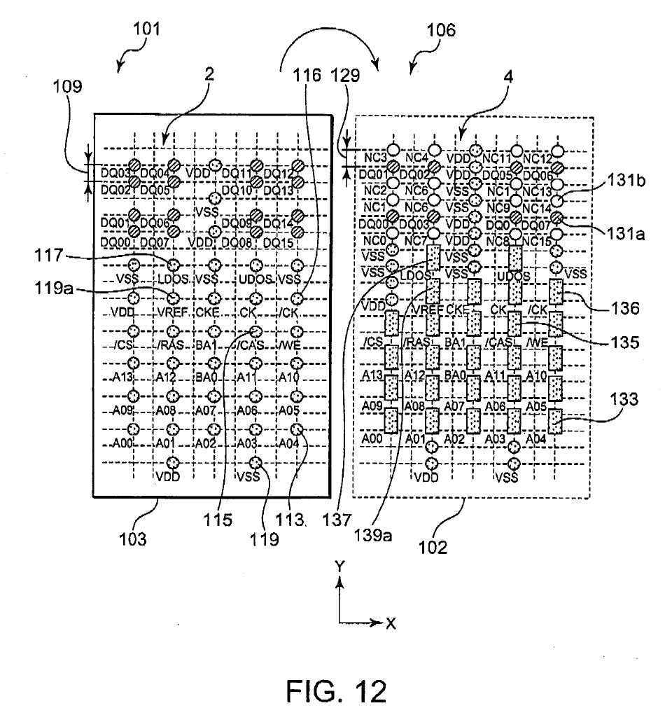

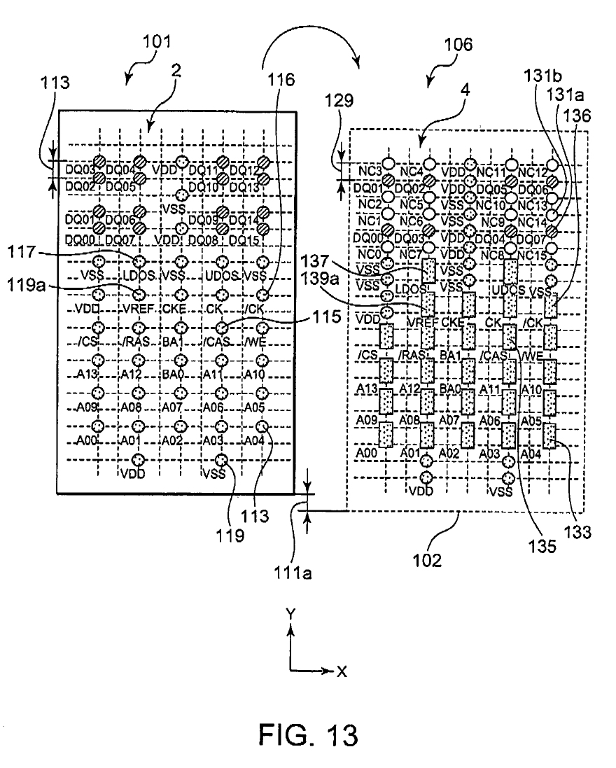

Next, additionally referring to FIG. 12 and FIG. 13, description will be made of a method for mounting the semiconductor device 101 when some of the input and output terminals 111 thereof are defective terminals.

It is assumed that at least some of the input and output terminals 111 indicated as DQ00, DQ02, DQ05, DQ07, DQ08, DQ10, DQ13 and DQ15 in FIG. 10 are defective terminals.

In this case, the semiconductor device 101 is mounted on the module substrate 106 such that the terminals other than the defective terminals (the normal terminals) face the conductive pads (the pads DQ00 to DQ07 in FIG. 11).

More specifically, as shown in FIG. 12, the position of the semiconductor device 101 is adjusted to the mounting portion 102 of the module substrate 106, and the semiconductor device 101 is mounted, without any change in position, on the module substrate 106. Then, the defective terminals of the input and output terminal pads 131 are connected to the positions corresponding to the non-conductive pads 131b In the mounting portion 102, and hence these defective terminals are not used. As a result, the semiconductor device 101 can be remanufactured as a ×8 memory using the eight normal terminals only.

Next, it is assumed that at least some of the input and output terminals 111 indicated as DQ01, DQ03, DQ04, DQ06, DQ09, DQ11, DQ12 and DQ14 shown in FIG. 10 are defective terminals.

In this case, if the input and output terminals 111 are connected in the same manner as when at least some of the terminals DQ00, DQ02, DQ05, DQ07, DQ08, DQ10, DQ13 and DQ15 are defective, the defective terminals will be connected to the conductive pads 131a. Therefore, the semiconductor device 101 is shifted from the position shown in FIG. 12 upwards in the Y direction by a distance 111a equal to the terminal interval 109 (see FIG. 13), and then mounted on the module substrate 106.

Then, as shown in FIG. 13, the conductive pads 131a of the input and output terminal pads 131 are connected to the positions corresponding to the terminals DQ00, DQ02, DQ05, DQ07, DQ08, DQ10, DQ13 and DQ15 (normal terminals) in the mounting portion 102. On the other hand, the non-conductive pads 131b are connected to the positions corresponding to the terminals DQ01, DQ03, DQ04, DQ06, DQ09, DQ11, DQ12 and DQ14 (defective terminals) in the mounting portion 102. As a result, the semiconductor device 101 can be remanufactured as a ×8 memory using only the eight terminals DQ00, DQ02, DQ05, DQ07, DQ08, DQ10, DQ13 and DQ15.

In this manner, even if either the first group (DQ00, DQ02, DQ05, DQ07, DQ08, DQ10, DQ13, DQ15) or the second group (DQ01, DQ03, DQ04, DQ06, DQ09, DQ11, DQ12, DQ14) of the input and output terminal pads 131 is defective in the mounting portion 102, only the normal terminals can be mounted on the conductive pads 131a by shifting the semiconductor device 101 to the Y direction relative to the mounting portion 102 (or by directly mounting the semiconductor device 101 on the mounting portion 102), so that the semiconductor device can be remanufactured as a ×8 memory using only the eight input and output terminals 111.

Therefore, there is no need of laying out the wirings according to the positions of the defective terminals, and thus the configuration on the substrate is simpler than that of a conventional substrate for remanufacturing.

Further, there are only two selectable methods for mounting the semiconductor device on the substrate, namely, mounting the semiconductor device without changing the position thereof, or mounting the semiconductor device after shifting the same by a predetermined distance about the mounting portion. Therefore, it does not take much trouble to mount the semiconductor device.

Since the input and output terminal pads 131, the address terminal pads 133, the command terminal pads 135, the clock terminal pads 136, and the strobe terminal pads 137 are formed in a rectangular shape extending in the Y direction and to extend beyond the adjacent two cross points of the lattice pattern, they can be connected to the respective corresponding terminals, even if the semiconductor device is shifted about the mounting portion, in the same manner as when the semiconductor device is mounted without changing its mounting position.

An electronic device according to the third embodiment, as described above, includes a semiconductor device having 16 input and output terminals 11, and a module substrate having a mounting portion having 24 input and output terminal pads, and is designed such that the semiconductor device can be mounted by shifting the same in a predetermined direction according to a position of a defective terminal.

Accordingly, the third embodiment also provides beneficial effects equivalent to those of the first embodiment.

While the present invention has been particularly shown and described with reference to exemplary embodiments thereof, the present invention is not limited to these embodiments. It will be understood by those of ordinary skill in the art that various changes in form and details may be made therein without departing from the sprit and scope of the present invention as defined by the claims.

Although in the exemplary embodiments described above, the present invention is applied to an electronic device in which a ×16 (16-terminal) semiconductor memory is remanufactured as a ×8 (8-terminal) semiconductor memory, the present invention is not limited to this. The present invention is applicable to any other structure for remanufacturing a semiconductor device having a defective terminal,

Further, although in the exemplary embodiments, the non-conductive pads have the same configuration as the conductive pads, the non-conductive pads need not have the same configuration as the conductive pads if an enough non-conductive space is ensured.

The present invention may be implemented by the following modes.

(First Mode)

An electronic device comprising a semiconductor device and a substrate for mounting the semiconductor device thereon, wherein:

the semiconductor device comprises a plurality of terminals provided on a surface of the semiconductor device facing the substrate;

the plurality of terminals are arranged at equal distances from a first center point on the surface of the semiconductor device, and include normal terminals which are conductive with the semiconductor device and defective terminals which are not conductive with the semiconductor device;

the substrate has a plurality of pads provided on a surface of the substrate facing the semiconductor device to connect to the plurality of terminals;

the plurality of pads are arranged at equal distances from a second center point on the surface of the substrate and at positions corresponding to the plurality of terminals, and include a first group of pads which can be electrically connected to the semiconductor device and a second group of pads which cannot be electrically connected to the semiconductor device; and

the semiconductor device is mounted on the substrate such that the plane coordinates of the first center point match with the plane coordinates of the second center point, and such that the normal terminals face the first group of pads and the defective terminals face the second group of pads.

(Second Mode)

The electronic device as mentioned in the above first mode, wherein the plurality of terminals and the plurality of pads are arranged along the circumferences of circles with the same diameter formed around the first center point and the second center point, respectively, the plurality of pads being arranged at equal intervals.

(Third Mode)

The electronic device as mentioned in the above second mode, wherein the first group of pads are arranged at equal intervals such that each of the first group of pads is interposed between two of the second group of pads.

(Fourth Mode)

The electronic device as mentioned in the above second mode,

wherein:

the semiconductor device is mounted on the substrate in the state in which the semiconductor device is rotated by a predetermined angle around the first center point; and

the predetermined angle is either an angle of a formed at the first center point by two lines connecting the first center point and two of the terminals adjacent to each other with a minimum distance, or an angle of β formed at the second center point by two lines connecting the second center point and two of the pads adjacent to each other with a minimum distance, the angle α and the angle β being equal to each other.

(Fifth Mode)

The electronic device as mentioned in the above fourth mode, wherein:

the plurality of terminals are composed of a plurality of pairs of terminals, each pair consisting of two terminals arranged to form an angle of a at the first center point; and

the plurality of pairs of terminals are arranged such that each adjacent two pairs of terminals form an angle of 2a at the first center point.

(Sixth Mode)

The electronic device as mentioned in the above fourth mode, wherein:

the semiconductor device further includes another terminal provided between the plurality of terminals and the first center point;

the substrate further has another pad provided between the plurality of pads and the second center point to connect to the other terminal; and

the other pad has a circular arc shape subtending the predetermined angle.

(Seventh Mode)

The electronic device as mentioned in the above fourth mode, wherein:

the semiconductor device further includes another terminal provided between the first center point and the plurality of terminals;

the substrate further has another pad provided between the second center point and the plurality of pads to connect to the other terminal; and

the other pad is composed of a plurality of pad pieces arranged within a range determined by the predetermined angle.

(Eighth Mode)

A substrate for remanufacturing a semiconductor device, comprising a surface on which a plurality of pads are arranged to connect to a plurality of terminals of the semiconductor device including a defective terminal, wherein:

the plurality of pads include a first group of pads which can be electrically connected to the plurality of terminals, and a second group of pads which cannot be electrically connected to the plurality of terminals; and

the first group of pads and the second group of pads are arranged at equal distances from a center point on the surface of the substrate.

(Ninth Mode)

The substrate for remanufacturing a semiconductor device as mentioned in the above eighth mode, wherein the plurality of pads are arranged at equal intervals along the circumference of a circle formed around the center point.

(Tenth Mode)

The substrate for remanufacturing a semiconductor device as mentioned in the above ninth mode, wherein the first group of pads are arranged at equal intervals such that each of the first group of pads is interposed between two of the second group of pads.

(Eleventh Mode)

The substrate for remanufacturing a semiconductor device as mentioned in the above eighth mode, further comprising another pad provided between the center point and the plurality of pads, the other pad having a circular arc shape.

(Twelfth Mode)

The substrate for remanufacturing a semiconductor device as mentioned in the above eighth mode, further comprising another pad provided between the center point and the plurality of pads, the other pad being composed of a plurality of pad pieces.

(Thirteenth Mode)

A semiconductor device comprising a plurality of terminals to connect to a substrate on a surface of the semiconductor device, and being designed to be able to be remanufactured, when a part of the plurality of terminals is defective, by connecting the same to the substrate for remanufacturing as mentioned in the above eighth mode.

(Fourteenth Mode)

The semiconductor device as mentioned in the above thirteenth mode, wherein the plurality of terminals are arranged along the circumference of a circle formed around a first center point on the surface of the semiconductor device.

(Fifteenth Mode)

The semiconductor device as mentioned in the above fourteenth mode, wherein:

the plurality of terminals are composed of a plurality of pairs of terminals, each pair consisting of two terminals arranged to form an angle of a at the first center point; and

the plurality of pairs of terminals are arranged such that each adjacent two pairs form an angle of 2a at the first center point.

(Sixteenth Mode)

An electronic device comprising a semiconductor device and a substrate for mounting the semiconductor device thereon, wherein:

the semiconductor device comprises a plurality of terminals provided on a surface of the semiconductor device facing the substrate;

the plurality of terminals are arranged in a lattice pattern and include normal terminals which are conductive with the semiconductor device and defective terminals which are not conductive with the semiconductor device;

the substrate has a plurality of pads provided on its surface facing the semiconductor device to connect to the plurality of terminals;

the plurality of pads are arranged in a lattice pattern, and include a first group of pads which can be electrically connected to the plurality of terminals and a second group of pads which cannot be electrically connected to the plurality of terminals; and

the semiconductor device is mounted on the substrate such that the normal terminals face the first group of pads and the defective terminal face the second group of pads.

(Seventeenth Mode)

The electronic device as mentioned in the above sixteenth mode, wherein the semiconductor device is mounted on the substrate while being shifted relative to the substrate by a distance corresponding to the interval between two adjacent cross points of the lattice pattern.

(Eighteenth Mode)

A substrate for remanufacturing a semiconductor device, comprising a surface on which a plurality of pads are arranged to connect to a plurality of terminals of the semiconductor device including a defective terminal, wherein:

the plurality of pads include a first group of pads which can be electrically connected to the plurality of terminals and a second group of pads which cannot be electrically connected to the plurality of terminals; and

the first group of pads and the second group of pads are arranged in a lattice pattern such that the first group of pads and the second group of pads are adjacent to each other in rows or columns of the lattice pattern.

(Nineteenth Mode)

The substrate for remanufacturing a semiconductor device as mentioned in the above eighteenth mode, wherein the plurality of pads further include another pad, and the other pad is formed to extend beyond adjacent two cross points of the lattice pattern.

(Twentieth Mode)

A method of arranging pads on a substrate for remanufacturing having on its surface a plurality of pads to connect to a plurality of terminals of a semiconductor device including a defective terminal, the method comprising:

(a) arranging a first group of pads which can be electrically connected to the plurality of terminals and a second group of pads which cannot be electrically connected to the plurality of terminals, at equal distances from a center point on the surface of the substrate.

(Twenty-First Mode)

The method of arranging pads on a substrate for remanufacturing as mentioned in the above twentieth mode, wherein the arranging (a) is a process in which the first group of pads and the second group of pads are arranged along the circumference of the same circle.

(Twenty-Second Mode)

The method of arranging pads on a substrate for remanufacturing as mentioned in the above twentieth mode, wherein the arranging (a) is a process in which each of the first group of pads is arranged between each two of the second group of pads.

(Twenty-Third Mode)

The method of arranging pads on a substrate for remanufacturing as mentioned in the above twentieth mode, further comprising:

(b) providing another pad between the center point and the first group of pads, the providing (b) being a process in which the other pad is formed to have a shape of a circular arc of a circle formed around the center point.

(Twenty-Fourth Mode)

The method of arranging pads on a substrate for remanufacturing as mentioned in the above twentieth mode, further comprising:

(b) providing another pad between the center point and the first group of pads, the providing (b) being a process in which the other pad is formed of a plurality of pad pieces.

(Twenty-Fifth Mode)

A method of remanufacturing a semiconductor device having a defective terminal by assembling the electronic device as mentioned in the above first mode, the method comprising:

mounting the semiconductor device on the substrate after rotating the semiconductor device by a predetermined angle around the first center point such that the plane coordinates of the first center point match with the plane coordinates of the second center point, and such that the normal terminals face the first group of pads while the defective terminals face the second group of pads.

What is claim is:

1. A substrate for mounting a semiconductor device which comprises a first group of input and output terminals, a second group of input and output terminals, and common terminals, the substrate comprising:
conductive pads that use for inputting and outputting data from and to the semiconductor device;
nonconductive pads that no use for inputting and outputting data from and to the semiconductor device; and
common pads formed so as to correspond to the common terminals;
wherein the second group of input and output terminals are connected to the non-conductive pads and the common terminals are connected to the common pads when the first group of input and output terminals are connected to the conductive pads, and wherein the first group of input and output terminals are connected to the non-conductive pads and the common terminals are connected to the common pads when the second group of input and output terminals are connected to the conductive pads.

2. The substrate for mounting a semiconductor device as claimed in claim 1; wherein the common pads include a pad which is larger in size than the conductive pads and the non-conductive pads.

3. The substrate for mounting a semiconductor device as claimed in claim 1, wherein the common pads include a first pad and a second pad, the first pad being connected to the corresponding terminal in the common terminals when the first group of input and output terminals are connected to the conductive terminals and being no connected to the common terminals when the second group of input and output terminals are connected to the conductive pads, the second pad being no connected to the common terminals when the first group of input and output terminals are connected to the conductive pads and being connected to the corresponding terminal in the common terminals when the second group of input and output terminals are connected to the conductive terminals.

4. The substrate for mounting a semiconductor device as claimed in claim 1; wherein the conductive pads and the non-conductive pads are arranged along a first direction.

5. The substrate for mounting a semiconductor device as claimed in claim 1; wherein the conductive pads and the non-conductive pads are arranged to form a circular arc shape along a circular arc.

6. The substrate for mounting a semiconductor device as claimed in claim 4; wherein the conductive pads are arranged such that each of the conductive pads is interposed between two of the non-conductive pads in the first direction.

7. The substrate for mounting a semiconductor device as claimed in claim 5, wherein the conductive pads are arranged such that each of the conductive pads is interposed between two of the non-conductive pads about the circular arc.

8. The substrate for mounting a semiconductor device as claimed in claim 1; wherein the conductive pads, the non-conductive pads, and the common pads are respectively arranged concentrically such that the pads of a same type are located at the same distance from a reference point.

9. The substrate for mounting a semiconductor device as claimed in claim 1; wherein the conductive pads, the non-conductive pads, and the common pads are respectively arranged in a lattice pattern.
